(19) United States
(12) Patent Application Publication
(10) Pub. No.: US 2024/0334765 A1
(43) Pub. Date: Oct. 3, 2024

(54) DISPLAY DEVICE

(71) Applicant: Samsung Display Co., Ltd., Yongin-Si (KR)

(72) Inventors: JONG HEON HAN, Yongin-si (KR); JINSEUK KIM, Yongin-si (KR); MINSUN JUNG, Yongin-si (KR)

(21) Appl. No.: 18/422,048

(22) Filed: Jan. 25, 2024

(30) Foreign Application Priority Data
Apr. 3, 2023 (KR) 10-2023-0043737

(51) Int. Cl. H10K 59/131; H10K 59/80

(52) U.S. Cl. CPC H10K 59/131; H10K 59/873

(57) ABSTRACT

A display device includes a substrate including a display area and a non-display area which includes a first non-display area, a second non-display area, an inorganic layer area, and a third non-display area including a bank area sequentially disposed in the non-display area, a data line extending in a first direction, a transfer line part overlapping the inorganic layer area and including first transfer lines and second transfer lines extending parallel to the first transfer lines and extending in a second direction intersecting the first direction, and a power line disposed in the first to third non-display areas and including a sub power line extending in the first direction and a branch protruding from one side of the sub power line and having a first edge and a second edge entirely overlapped with the transfer line part in a plan view.

This application claims priority to Korean Patent Application No. 10-2023-0043737, filed on Apr. 3, 2023, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

A display device is a device that displays an image to provide visual information to a user. The display device may include a display area and a non-display area.

A light emitting element emitting light and a transistor driving the light emitting element may be disposed in the display area. Drivers generating signals and/or voltages may be disposed in the non-display area. Lines connecting the drivers and the transistors may be disposed in the non-display area.

### SUMMARY

Embodiments provide a display device with improved durability.

A display device according to an embodiment may include a substrate including a display area, a first non-display area surrounding the display area, a second non-display area surrounding the first non-display area, and a third non-display area including a bank area spaced apart from the first non-display area with the second non-display area interposed therebetween and an inorganic layer area disposed between the second non-display area and the bank area, a data line disposed in the display area on the substrate and extending in a first direction, a protruding member disposed in the second non-display area on the substrate and including an organic material, a bank disposed in the bank area on the substrate and spaced apart from the protruding member, a transfer line part disposed on the substrate, overlapping the inorganic layer area, and including first transfer lines extending in a second direction intersecting the first direction and second transfer lines disposed parallel to the first transfer lines and extending in the second direction, and a power line disposed in the first to third non-display areas on the substrate and including a sub power line extending in the first direction and a branch protruding from one side of the sub power line and having a first edge and a second edge entirely overlapped with the transfer line part in a plan view.

In an embodiment, the branch may protrude from the one side of the sub power line such that the first edge and the second edge extend parallel to the first transfer lines and the second transfer lines.

In an embodiment, the first edge and the second edge may have a straight-line shape extending parallel to the first transfer lines and the second transfer lines.

In an embodiment, the first edge may entirely overlap with one of the first transfer lines in a plan view, and the second edge may entirely overlap with another one of the first transfer lines in a plan view.

In an embodiment, the first edge may entirely overlap with one of the second transfer lines in a plan view, and the second edge may entirely overlap with another one of the second transfer lines in a plan view.

In an embodiment, the second direction may be a direction which obliquely intersects the first direction.

In an embodiment, the first transfer lines and the second transfer lines may be alternately arranged.

In an embodiment, a layer on which the first transfer lines are disposed may be different from a layer on which the second transfer lines are disposed.

In an embodiment, the transfer line part may further include third transfer lines extending parallel to the first transfer lines and the second transfer lines, the first edge may entirely overlap with one of the third transfer lines in a plan view, and the second edge may entirely overlap with another one of the third transfer lines in a plan view.

In an embodiment, the first transfer lines, the second transfer lines, and the third transfer lines may be alternately arranged.

In an embodiment, a layer on which the first transfer lines are disposed, a layer on which the second transfer lines are disposed, and a layer on which the third transfer lines may be disposed are different from each other.

In an embodiment, the display device may further include a pixel electrode disposed in the display area, a light emitting layer disposed on the pixel electrode, a common electrode disposed on the light emitting layer, a first inorganic encapsulation layer disposed on the common electrode, an organic encapsulation layer disposed on the first inorganic encapsulation layer, and a second inorganic encapsulation layer disposed on the organic encapsulation layer, and the first inorganic encapsulation layer and the second inorganic encapsulation layer may directly contact each other in the inorganic layer area

In an embodiment, the substrate may further include a peripheral area surrounded by the display area and an opening area surrounded by the peripheral area, and the peripheral area may include a disconnection area in which the common electrode is disconnected.

In an embodiment, the display device may further include an electronic module overlapping the opening area in a plan view.

In an embodiment, a dam including an organic material is disposed in the peripheral area, and the disconnection area may be located on both sides of the dam.

A display device according to an embodiment may include a substrate including a display area and a non-display area surrounding the display area, a data line disposed in the display area on the substrate and extending in a first direction, a transfer line part disposed in the non-display area on the substrate, connected to the data line, and including first transfer lines extending in a second direction intersecting the first direction and second transfer lines disposed parallel to the first transfer lines and extending in the second direction, and a power line disposed in the non-display areas on the substrate and including a sub power line extending in the first direction and a branch protruding from one side of the sub power line and having a first edge and a second edge entirely overlapped with the transfer line part in a plan view.

In an embodiment, the branch may protrude from the one side of the sub power line such that the first edge and the second edge extend parallel to the first transfer lines and the second transfer lines.

In an embodiment, the first edge and the second edge may have a straight-line shape extending parallel to the first transfer lines and the second transfer lines.

In an embodiment, the second direction may be a direction which obliquely intersects the first direction.

In an embodiment, the first transfer lines and the second transfer lines may be alternately arranged.

In the display device according to embodiments, the display device may include the transfer line part and the power line disposed on the transfer line part, and the power line may include the sub power line and the branch protruding from one side of the sub power line. Accordingly, a length of a side surface of the power line may be longer than a length of a side surface of the power line not including the branch. Accordingly, a moisture permeation path of external air or moisture may be relatively long. Accordingly, permeation of external air or moisture through the side surface of the power line may be delayed or prevented.

In addition, the branch may protrude from one side of the sub power line such that edges are entirely overlapped with the transfer line part in a plan view. Also, the edges of the branch may extend parallel to the transfer line part. Accordingly, damage to the power line (e.g., the branch) due to external pressure or the like may be reduced or prevented. Accordingly, durability of the display device may be improved.

It is to be understood that both the foregoing general description and the following detailed description are exemplary and explanatory and are intended to provide further explanation of the inventive concept as claimed.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to an embodiment.

FIG. 2 is an enlarged view illustrating an enlarged area A of FIG. 1.

FIG. 3 is a cross-sectional view illustrating a display area of the display device of FIGS. 1 and 2.

FIG. 4 is a cross-sectional view illustrating a peripheral area and an opening area of the display device of FIGS. 1 and 2.

FIG. 5 is an enlarged view illustrating an enlarged area B of FIG. 1.

FIG. 6 is an enlarged view illustrating an example of area C of FIG. 5.

FIG. 7 is an enlarged view illustrating area D of FIG. 6.

FIG. 8 is a cross-sectional view taken along line I-I′ of FIG. 6.

FIG. 9 is a cross-sectional view taken along line II-II′ of FIG. 6.

FIG. 10 is a cross-sectional view taken along line III-III′ of FIG. 7.

FIG. 11 is an enlarged view illustrating an example of area C of FIG. 5.

FIG. 12 is an enlarged view illustrating an example of area C of FIG. 5.

FIG. 13 is a cross-sectional view taken along line IV-IV of FIG. 12.

FIG. 14 is an enlarged view illustrating an example of area C of FIG. 5.

### DETAILED DESCRIPTION

The inventive concept now will be described more fully hereinafter with reference to the accompanying drawings, in which various embodiments are shown. This inventive concept may, however, be embodied in many different forms, and should not be construed as limited to the embodiments set forth herein. Rather, these embodiments are provided so that this disclosure will be thorough and complete, and will fully convey the scope of the inventive concept to those skilled in the art. Like reference numerals refer to like elements throughout.

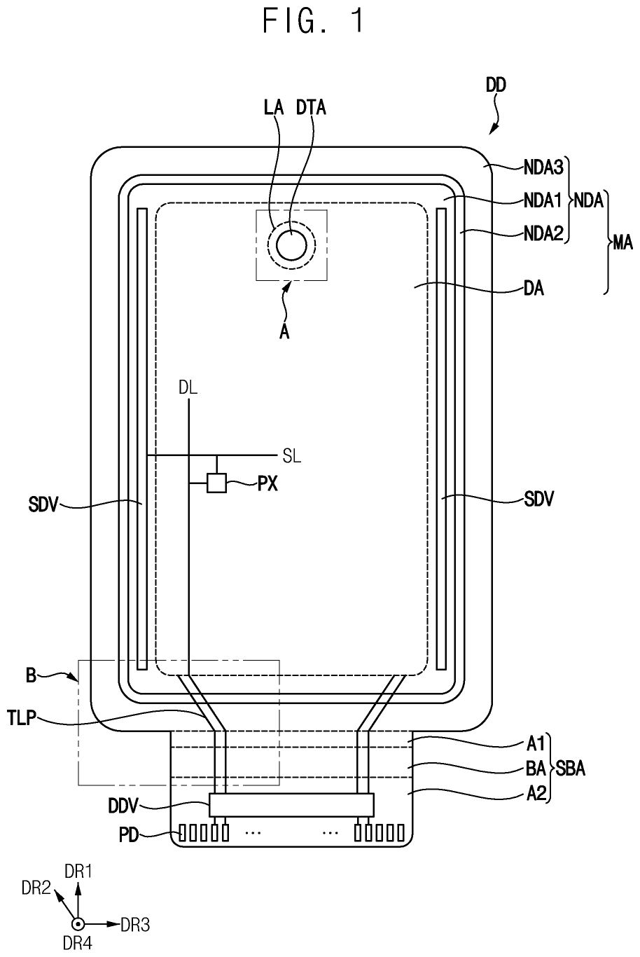

FIG. 1 is a plan view illustrating a display device according to an embodiment.

Referring to FIG. 1, a display device DD may display an image in a fourth direction DR4 on a plane defined by first and third directions DR1 and DR3. Here, the third direction DR3 may be a direction perpendicular to the first direction DR1. Meanwhile, in a present specification, a second direction DR2 may be a direction which obliquely intersects the first direction DR1. Front and rear surfaces of each member included in the display device DD are defined by the fourth direction DR4. Meanwhile, directions indicated by the first to fourth directions DR1, DR2, DR3, and DR4 may be defined as directions other than described hereinabove and may be a relative concept. Meanwhile, a planar shape of the display device DD is not limited to a quadrangle and may be formed in a polygonal shape, a circular shape, or an elliptical shape other than quadrangle.

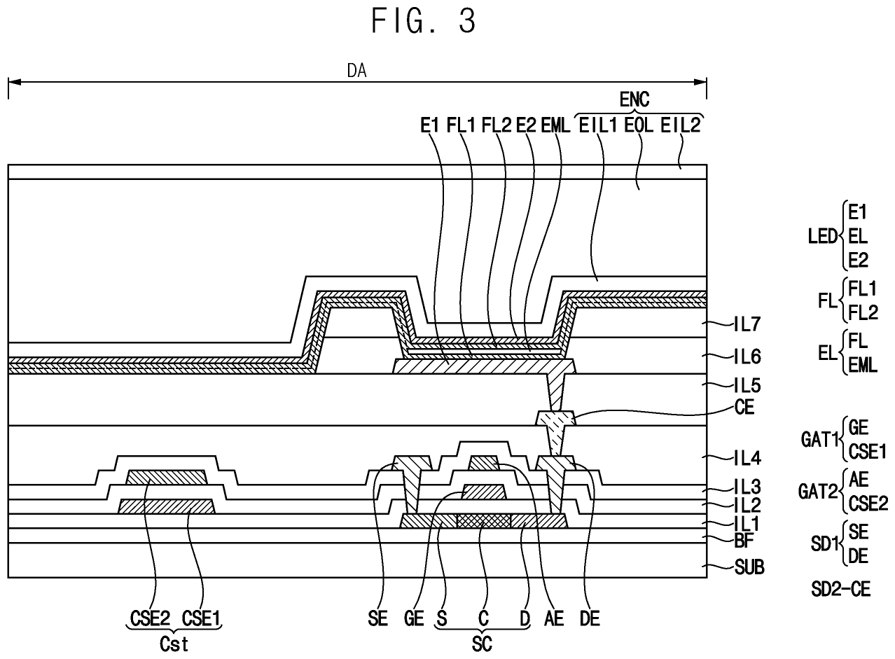

The display device DD (e.g., a substrate SUB of FIG. 3) may include a main area MA and a sub area SBA.

The main area MA may include a display area DA displaying an image and a non-display area NDA positioned around the display area DA. For example, the non-display area NDA may surround the display area DA. An opening area DTA may be positioned in the display area DA.

The non-display area NDA may include a first non-display area NDA1, a second non-display area NDA2, and a third non-display area NDA3. The first non-display area NDA1 may surround the display area DA, the second non-display area NDA2 may surround the first non-display area NDA1, and the third non-display area NDA3 may surround the second non-display area NDA2.

In other words, the first non-display area NDA1 may be disposed between the display area DA and the second non-display area NDA2, and the second non-display area NDA2 may be disposed between the first non-display area NDA1 and the third non-display area NDA3. That is, the first non-display area NDA1 may be disposed inside the second non-display area NDA2, and the third non-display area NDA3 may be disposed outside the second non-display area NDA2.

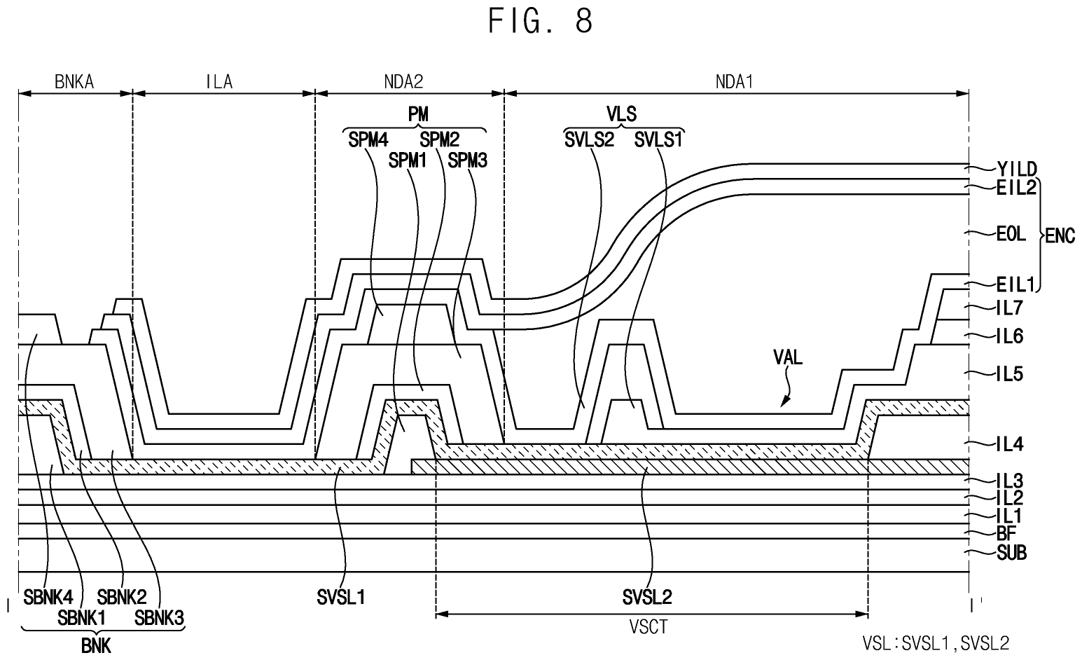

The second non-display area NDA2 may be an area where a protruding member (PM in FIG. 8) is disposed. The protruding member PM may prevent an organic encapsulation layer (EOL in FIG. 3) of an encapsulation layer (ENC in FIG. 3) for sealing light emitting devices of the display area DA from overflowing to the third non-display area NDA3.

The sub area SBA may protrude from one side of the main area MA in a direction opposite to the first direction DR1. In an embodiment, a length of the sub area SBA in the third direction DR3 may be shorter than a length of the main area MA in the third direction DR3. However, the present inventive concept is not necessarily limited thereto. The sub area SBA may be bent and a portion of the sub area SBA may be disposed on a rear surface of the display device DD. In this case, the portion of the sub area SBA may overlap the main area MA in the fourth direction DR4.

The sub area SBA may include a first area A1, a second area A2, and a bending area BA.

The first area A1 may protrude from the one side of the main area MA in a direction opposite to the first direction DR1. One side of the first area A1 may contact the non-display area NDA of the main area MA, and the other side of the first area A1 may contact the bending area BA.

The second area A2 may be an area where a pad part PD and a data driver DDV are disposed. The pad part PD may be electrically connected to an external device (e.g., a printed circuit board). One side of the second area A2 may contact the bending area BA.

The bending area BA may be bent. When the bending area BA is bent, the second area A2 may be disposed under the first area A1 and under the main area MA. The bending area BA may be disposed between the first area A1 and the second area A2. One side of the bending area BA may contact the first area A1 and the other side of the bending area BA may contact the second area A2.

The display device DD may include pixels PX. The pixels PX may be disposed in the display area DA. Each of the pixels PX may include a light emitting element and a transistor connected to the light emitting element. In an embodiment, the each of the pixels PX may emit red, green, blue, or white light.

The display device DD may include a plurality of lines. The lines may include data lines DL extending in the first direction DR1 and scan lines SL extending in the third direction DR3.

A data driver DDV may be disposed in the sub area SBA. Specifically, the data driver DDV may be disposed in the second area A2. More specifically, the data driver DDV may be disposed between the display area DA and the pad part PD. The data driver DDV may generate data voltages. The data voltages may be transferred to the pixels PX through the data lines DL.

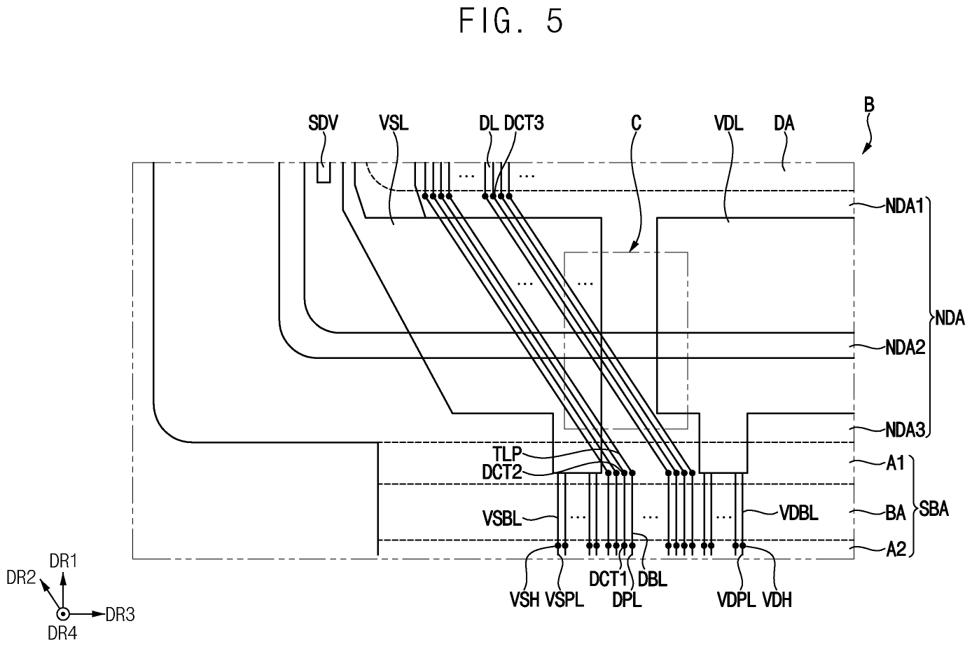

The data lines DL may be electrically connected to the data driver DDV through a transfer line part TLP. That is, the data voltages generated by the data driver DDV may be transferred to the data lines DL through the transfer line part TLP. In an embodiment, the transfer line part TLP may overlap the non-display area NDA and may be connected to the data lines DL. In other words, the transfer line part TLP may be disposed between the data driver DDV and the display area DA. The transfer line part TLP may extend obliquely to the second direction DR2. The transfer line part TLP will be described later in detail with reference to FIGS. 5 to 7.

A scan driver SDV may be disposed in the non-display area NDA. The scan driver SDV may be positioned on left and right sides of the display area DA. For example, the scan driver SDV may be disposed in the first non-display area NDA1. However, the present inventive concept is not necessarily limited thereto, and the scan driver SDV may be disposed in the third non-display area NDA3. The scan driver SDV may generate scan signals. The scan signals may be transferred to the pixels PX through the scan lines SL.

Meanwhile, the lines may further include a power voltage line (not shown) for transferring a power voltage to the pixel PX.

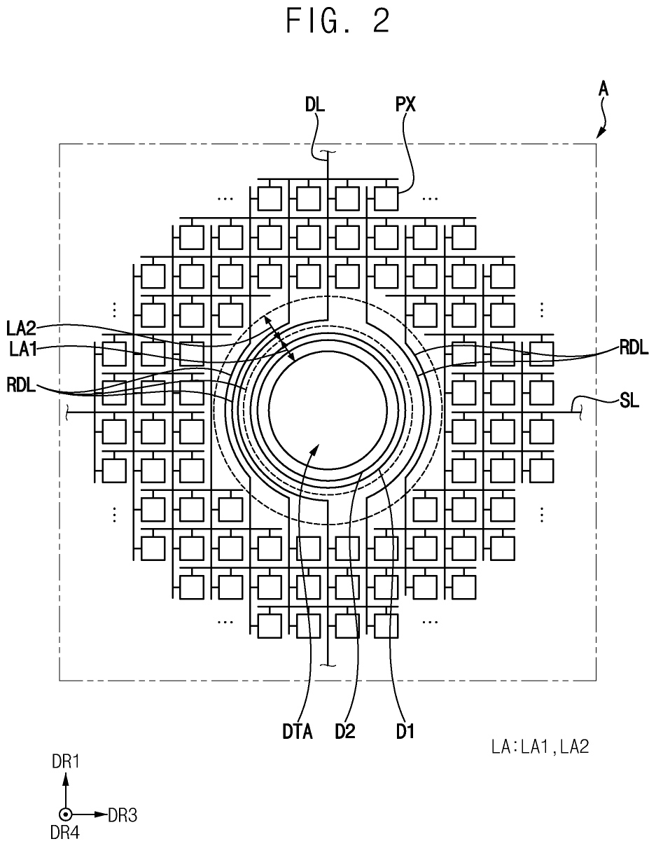

FIG. 2 is an enlarged view illustrating an enlarged area A of FIG. 1.

Referring to FIGS. 1 and 2, as described above, the display device DD may include the data lines DL, the scan lines SL, and the pixels PX. The pixels PX may be connected to the data lines DL and the scan lines SL.

The display device DD (e.g., the substrate SUB of FIG. 3) may further include the opening area DTA through which at least one electronic module such as a camera, a speaker, or a sensor for detecting light or heat is exposed and a peripheral area LA. The opening area DTA may be surrounded by the peripheral area LA, and the peripheral area LA may be surrounded by the display area DA. That is, the peripheral area LA may be an area surrounding outside of the opening area DTA and may be an intermediate area between the display area DA and the opening area DTA. The peripheral area LA may include a first peripheral area LA1 and a second peripheral area LA2.

The first peripheral area LA1 may include an area to which laser is irradiated to remove some layers. In addition, first and second dams D1 and D2 may be disposed in the first peripheral area LA1. The first peripheral area LA1 may be an area that prevents damage to elements and lines located in the display area DA even when a process of cutting out the opening area DTA is performed after laser irradiation.

The second peripheral area LA2 may be an area where a portion (RDL, hereinafter referred to as a bypass portion) in which the data line DL extends along a periphery of the opening area DTA is disposed. As a result, even though the data line DL cannot have a linear shape due to the opening area DTA, the pixels PX positioned above and below the opening area DTA may be connected to one data line DL due to the bypass portion RDL extending along the periphery of the opening area DTA.

The first peripheral area LA1 may be located closer to the opening area DTA than the second peripheral area LA2, and the second peripheral area LA2 may be located closer to the display area DA than the first peripheral area LA1.

Meanwhile, the scan line SL of the pixel PX located on a left side of the opening area DTA may be electrically connected only to the scan driver SDV located on the left side of the display area DA, and the scan line SL of the pixel PX located on a right side of the opening area DTA may be electrically connected only to the scan driver SDV located on the right side of the display area DA. That is, the scan lines SL connected to the pixels PX located on the left side of the opening area DTA and the scan lines SL connected to the pixels PX located on the right side of the opening area DTA may be disconnected at the opening area DTA. However, the present inventive concept is not necessarily limited thereto, and in another example, the scan lines SL located on the left and right sides of the opening area DTA may be connected to each other in a bypass portion in which bypass scan lines which connect the scan lines SL located on the left right side of the opening area DTA and the scan lines SL located on right side of the opening area DTA are disposed.

FIG. 3 is a cross-sectional view illustrating a display area of the display device of FIGS. 1 and 2, and FIG. 4 is a cross-sectional view illustrating a peripheral area and an opening area of the display device of FIGS. 1 and 2.

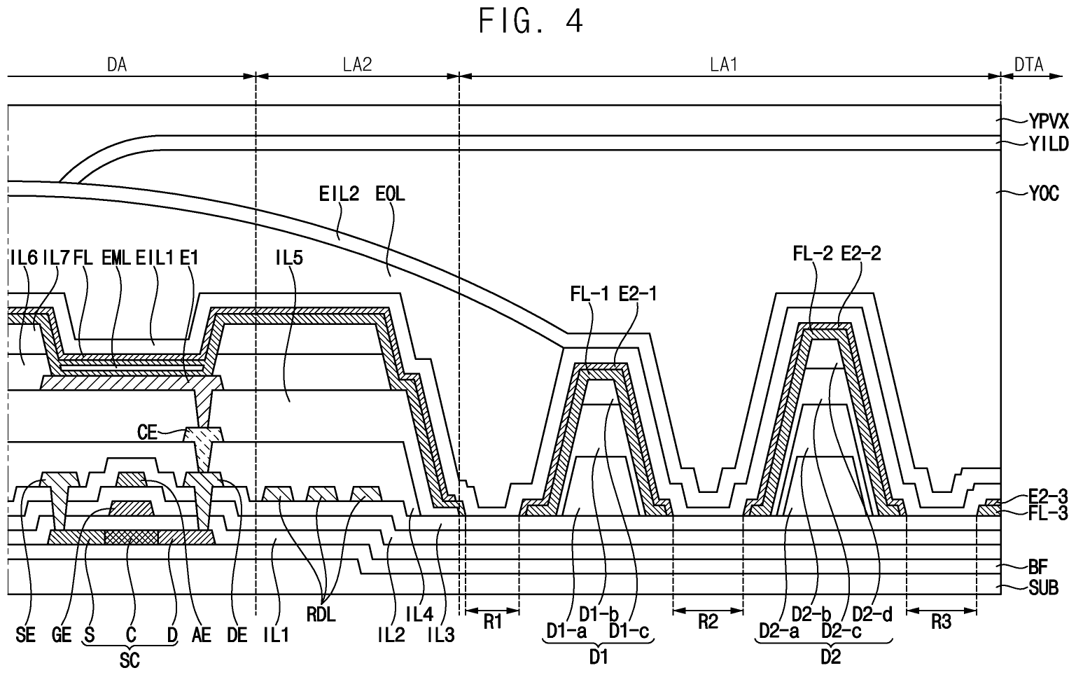

Hereinafter, a cross-sectional structure of the display device DD will be described with further reference to FIGS. 3 and 4.

First, a cross-sectional structure of the display area DA of the display device DD will be described with reference to FIGS. 1 and 3.

The display device DD may include a substrate SUB, a buffer layer BF, a semiconductor layer SC, a first inorganic insulating layer IL1, a first gate conductive layer GAT1, a second inorganic insulating layer IL2, a second gate conductive layer GAT2, a third inorganic insulating layer IL3, a first data conductive layer SD1, a first organic insulating layer ILA, a second data conductive layer SD2, a second organic insulating layer IL5, a first electrode E1, a pixel defining layer IL6, a spacer IL7, an intermediate layer EL, a second electrode E2, and an encapsulation layer ENC.

The substrate SUB may include an inorganic insulating material such as glass or an organic insulating material such as plastic, for example, polyimide (PI). The substrate SUB may have a single layer or multiple layers. The substrate SUB may have a structure in which at least one base layer including a polymer resin and at least one inorganic layer are alternately stacked.

The buffer layer BF may be disposed on the substrate SUB. The buffer layer BF may block a transfer of impurities from the substrate SUB to an upper layer of the buffer layer BF, particularly the semiconductor layer SC, thereby preventing deterioration of the characteristics of the semiconductor layer SC and relieving stress. The buffer layer BF may include an inorganic insulating material such as silicon nitride or silicon oxide or an organic insulating material.

The semiconductor layer SC may be disposed on the buffer layer BF. The semiconductor layer SC may include polycrystalline silicon. The semiconductor layer SC may include a channel region C, a source region S and a drain region D. The channel region C may be a semiconductor region lightly doped with impurities or not doped with impurities compared to the source region S and the drain region D, and the source region S and the drain region D may be semiconductor regions heavily doped with impurities than the channel region C.

The first inorganic insulating layer IL1 may be disposed on the semiconductor layer SC. The first inorganic insulating layer IL1 may have a single-layer or multi-layer structure including at least one of silicon oxide (SiOx), silicon nitride (SiNx), and silicon nitride (SiOxNy).

The first gate conductive layer GAT1 may be disposed on the first inorganic insulating layer IL1. In an embodiment, the first gate conductive layer GAT1 may include a gate electrode GE and a first capacitor electrode CSE1. The gate electrode GE and the first capacitor electrode CSE1 may be different portions of one conductive pattern. The first gate conductive layer GAT1 may include at least one of copper (Cu), a copper alloy, aluminum (Al), an aluminum alloy, molybdenum (Mo), a molybdenum alloy, titanium (Ti), and a titanium alloy. The first gate conductive layer GAT1 may have a single-layer or multi-layer structure. The gate electrode GE may overlap the channel region C of the semiconductor layer SC in a plan view.

The second inorganic insulating layer IL2 may be disposed on the first inorganic insulating layer IL1 and the first gate conductive layer GAT1. The second inorganic insulating layer IL2 may have a single-layer or multi-layer structure including at least one of silicon oxide (SiOx), silicon nitride (SiNx), and silicon nitride (SiOxNy).

The second gate conductive layer GAT2 may be disposed on the second inorganic insulating layer IL2. In an embodiment, the second gate conductive layer GAT2 may include an upper electrode AE and a second capacitor electrode CSE2. The upper electrode AE and the second capacitor electrode CSE2 may be different portions of one conductive pattern. The second gate conductive layer GAT2 may include at least one of copper (Cu), a copper alloy, aluminum (Al), an aluminum alloy, molybdenum (Mo), a molybdenum alloy, titanium (Ti), and a titanium alloy. The second gate conductive layer GAT2 may have a single-layer or multi-layer structure.

The first capacitor electrode CSE1 and the second capacitor electrode CSE2 may overlap to form a storage capacitor Cst.

The third inorganic insulating layer IL3 may be disposed on the second inorganic insulating layer IL2 and the second gate conductive layer GAT2. The third inorganic insulating layer IL3 may have a single-layer or multi-layer structure including at least one of silicon oxide (SiOx), silicon nitride (SiNx), and silicon nitride (SiOxNy).

The first data conductive layer SD1 may be disposed on the third inorganic insulating layer IL3. In an embodiment, the first data conductive layer SD1 may include a source electrode SE and a drain electrode DE which are separated from each other. The source electrode SE and the drain electrode DE may be different portions of one conductive pattern. The source electrode SE and the drain electrode DE may be electrically connected to the source region S and drain region D of the semiconductor layer SC through contact holes formed in the first to third inorganic insulating layers IL1, IL2, and IL3, respectively. The first data conductive layer SD1 may include at least one of aluminum (Al), silver (Ag), magnesium (Mg), gold (Au), nickel (Ni), chromium (Cr), nickel (Ni), calcium (Ca), molybdenum (Mo), titanium (Ti), tungsten (W), and copper (Cu). The first data conductive layer SD1 may have a single-layer or multi-layer structure.

The first organic insulating layer IL4 may be disposed on the third inorganic insulating layer IL3 and the first data conductive layer SD1. The first organic insulating layer IL4 may include a general-purpose polymer such as polymethylmethacrylate (PMMA) or polystyrene (PS), a polymer derivative having a phenolic group, and an organic insulating material such as an acrylic polymer, an imide polymer, a polyimide, an acrylic polymer, a siloxane polymer, or the like.

The second data conductive layer SD2 may be disposed on the first organic insulating layer IL4. The second data conductive layer SD2 may include a connection electrode CE. The connection electrode CE may be a portion of one conductive pattern. The connection electrode CE may connect the drain electrode DE and the first electrode E1. The second data conductive layer SD2 may include at least one of aluminum (Al), silver (Ag), magnesium (Mg), gold (Au), nickel (Ni), chromium (Cr), nickel (Ni), calcium (Ca), molybdenum (Mo), titanium (Ti), tungsten (W), and copper (Cu). The first data conductive layer SD1 may have a single-layer or multi-layer structure.

The second organic insulating layer IL5 may be disposed on the first organic insulating layer IL4 and the second data conductive layer SD2. The second organic insulating layer IL5 may include a general-purpose polymer such as polymethylmethacrylate (PMMA) or polystyrene (PS), a polymer derivative having a phenolic group, and an organic insulating material such as an acrylic polymer, an imide polymer, a polyimide, an acrylic polymer, a siloxane polymer, or the like.

The first electrode E1 may be disposed on the second organic insulating layer IL5. The first electrode E1 may be connected to the connection electrode CE through a contact hole formed in the second organic insulating layer IL5. That is, the first electrode E1 may be electrically connected to the drain electrode DE. The first electrode E1 may include a metal such as silver (Ag), lithium (Li), calcium (Ca), aluminum (Al), magnesium (Mg), or gold (Au), and may include a transparent conductive oxide (TCO) such as indium tin oxide (ITO), indium zinc oxide (IZO). The first electrode E1 may have a single-layer or multi-layer structure.

The pixel defining layer IL6 and the spacer IL7 may be disposed on the first electrode E1 and the second organic insulating layer IL5. The pixel defining layer IL6 may overlap at least a portion of the first electrode E1 and have a pixel opening defining an emission area.

The pixel definition layer IL6 and the spacer IL7 may include a general-purpose polymer such as polymethylmethacrylate (PMMA) or polystyrene (PS), a polymer derivative having a phenolic group, and an organic insulating material such as an acrylic polymer, an imide polymer, a polyimide, an acrylic polymer, a siloxane polymer, or the like. The pixel definition layer IL6 and the spacer IL7 may be formed of the same material and formed at the same time.

The intermediate layer EL may be disposed on the first electrode E1, the pixel defining layer IL6, and the spacer IL7. The intermediate layer EL may include a light emitting layer EML and a functional layer FL. The light emitting layer EML may generate light having a predetermined color. The light emitting layer EML may include an organic material and/or an inorganic material. In an embodiment, the light emitting layer EML may be disposed only in the pixel opening. In another example, the light emitting layer EML may be disposed over a plurality of pixels.

Meanwhile, the functional layer FL may include at least one of a hole injection layer (HIL), a hole transporting layer (HTL), an electron transporting layer (ETL), and an electron injection layer (EIL). The functional layer FL may include a first functional layer FL1 positioned between the first electrode E1 and the light emitting layer EML and a second functional layer FL2 positioned between the light emitting layer EML and the second electrode E2. The functional layer FL may be disposed over a plurality of pixels.

The second electrode E2 may be disposed on the intermediate layer EL. The second electrode E2 may include a metal such as calcium (Ca), barium (Ba), magnesium (Mg), aluminum (Al), silver (Ag), platinum (Pt), palladium (PD), gold (Au), and nickel (Ni), neodymium (Nd), iridium (Ir), chromium (Cr), and lithium (Li), or a transparent conductive oxide (TCO) such as indium tin oxide (ITO) and indium zinc oxide (IZO).

The first electrode E1, the intermediate layer EL, and the second electrode E2 may form a light emitting element LED. In an embodiment, the first electrode E1 may be an anode that is a hole injection electrode, and the second electrode E2 may be a cathode that is an electron injection electrode. However, the present inventive concept is not necessarily limited thereto, and the first electrode E1 may serve as a cathode and the second electrode E2 may serve as an anode according to a driving method of a display device.

The gate electrode GE and the semiconductor layer SC may form a transistor. In an embodiment, the transistor may be connected to the first electrode E1 to supply current to the light emitting element LED.

The encapsulation layer ENC may be disposed on the second electrode E2. The encapsulation layer ENC may cover the light emitting element LED. The encapsulation layer ENC may block inflow of external moisture and oxygen by sealing the light emitting element LED. The encapsulation layer ENC may include at least one inorganic encapsulation layer and at least one organic encapsulation layer. In an embodiment, the encapsulation layer ENC may include a first inorganic encapsulation layer EIL1 disposed on the second electrode E2, an organic encapsulation layer EOL disposed on the first inorganic encapsulation layer EIL1, and a second inorganic encapsulation layer EIL2 disposed on the organic encapsulation layer EOL.

Hereinafter, cross-sectional structures of the peripheral area LA and the opening area DTA of the display device DD will be described with reference to FIGS. 1, 2, and 4.

Referring to FIGS. 1, 2 and 4, the cross-sectional structure of the display area DA extends to the peripheral area LA and the opening area DTA, and as a result, the peripheral area LA and the opening area DTA may have a cross-sectional structure as shown in FIG. 4.

Meanwhile, FIG. 4 clearly illustrates that no structure is formed in the opening area DTA, and additional insulating layers (an overcoat layer YOC, a touch insulating layer YILD, and a planarization layer YPVX) are further illustrated. Depending on embodiments, at least some of the additional insulating layers may be omitted. Also, according to an embodiment, a touch electrode for sensing a touch may be additionally disposed between the encapsulation layer ENC and the planarization layer YPVX in the display area DA.

The peripheral area LA may include the first peripheral area LA1 and the second peripheral area LA2. Meanwhile, in FIG. 4, the first peripheral area LA1 has a wider width than the second peripheral area LA2, but the present inventive concept is not necessarily limited thereto.

The dams D1 and D2 may be disposed in the first peripheral area LA1. The first peripheral area LA1 may include a first disconnection area R1, a second disconnection area R2, and a third disconnection area R3. The first disconnection area R1, the second disconnection area R2, and the third disconnection area R3 may be areas in which the functional layer FL and the second electrode E2 are removed.

Meanwhile, the first peripheral area LA1 may also include an area where the laser is irradiated to a sacrificial layer to form the first disconnection area R1, the second disconnection area R2, and the third disconnection area R3. For example, the first disconnection area R1, the second disconnection area R2, and the third disconnection area R3 may be formed by removing a portion of the functional layer FL and a portion of the second electrode E2 along with the sacrificial layer formed of metal by irradiating the laser. The laser may be irradiated over the dams D1 and D2 and the first to third disconnected areas R1, R2, and R3. The first peripheral area LA1 may be an area that prevents damage to elements and lines located in the display area DA during a process of cutting out the opening area DTA after laser irradiation.

The second peripheral area LA2 may be an area where the bypass portion RDL is disposed. The bypass portion RDL may be a portion of the data line DL extending along the periphery of the opening area DTA. In an embodiment, the bypass portion RDL may be included in the first data conductive layer SD1 and may be disposed on the third inorganic insulating layer IL3.

The buffer layer BF, the first inorganic insulating layer IL1, the second inorganic insulating layer IL2, and the third inorganic insulating layer IL3 may be disposed in the peripheral area LA on the substrate SUB. That is, the buffer layer BF, the first inorganic insulating layer IL1, the second inorganic insulating layer IL2, and the third inorganic insulating layer IL3 may continuously extend from the display area DA to the peripheral area LA.

In the second peripheral area LA2, the bypass portion RDL may be disposed on the third inorganic insulating layer IL3, and the first organic insulating layer IL4, the second organic insulating layer IL5, the pixel defining layer IL6, the spacer IL7, the functional layer FL, the second electrode E2, and the encapsulation layer ENC may be continuously disposed on the bypass portion RDL. In addition, the overcoat layer YOC, the touch insulating layer YILD, and the planarization layer YPVX, which are additional insulating layers, may be further disposed on the encapsulation layer ENC.

Meanwhile, in the first peripheral area LA1, portions where the dams D1 and D2 are located and the first to third disconnected areas R1, R2, and R3 may have different layered structures.

First, a layered structure of the first to third disconnection areas R1, R2, and R3 will be described as follows.

In the first to third disconnection areas R1, R2, and R3, the substrate SUB, the buffer layer BF, the first inorganic insulating layer IL1, the second inorganic insulating layer IL2, the third inorganic insulating layer IL3, the first inorganic encapsulation layer EIL1, and the second inorganic encapsulation layer EIL2 may be sequentially stacked. However, the organic encapsulation layer EOL may be further disposed between the first inorganic encapsulation layer EIL1 and the second inorganic encapsulation layer EIL2 in the first disconnection area R1 located close to the display area DA. Depending on the embodiment, the organic encapsulation layer EOL may be further disposed up to the second disconnection area R2 or the third disconnection area R3. However, since it is suitable for the organic encapsulation layer (EOL) of the encapsulation layer (ENC) to be disposed so as not to be exposed to the outside to block moisture and oxygen, an end of the organic encapsulation layer EOL may not be exposed to the outside by being covered by the first inorganic encapsulation layer EIL1 and the second inorganic encapsulation layer EIL2.

That is, in the layered structure of the first disconnection area R1, the second disconnection area R2, and the third disconnection area R3, the functional layer FL and the second electrode E2 may be disconnected.

A layered structure of a portion of the first peripheral area LA1 where the dams D1 and D2 are located is as follows.

In the first peripheral area LA1, the first dam D1 and the second dam D2 may be sequentially positioned. The first dam D1 and the second dam D2 may be disposed on the substrate SUB, the buffer layer BF, the first inorganic insulating layer IL1, the second inorganic insulating layer IL2, and the third inorganic insulating layer IL3.

The first dam D1 may include a 1-1st sub-dam D1-a, a 1-2nd sub-dam D1-b, and a 1-3rd sub-dam D1-c. The 1-1st sub-dam D1-a may be positioned on the same layer as the second organic insulating layer IL5 positioned in the display area DA and may include the same material. The 1-1st sub-dam D1-a may be formed in the same process as the second organic insulating layer IL5 positioned in the display area DA. The 1-2nd sub-dam D1-b may be positioned on the same layer as the pixel defining layer IL6 positioned in the display area DA and may include the same material. The 1-2nd sub-dam D1-b may be formed in the same process as the pixel defining layer IL6 positioned in the display area DA. The 1-3rd sub-dam D1-c may be positioned on the same layer as the spacer IL7 positioned in the display area DA and may include the same material. The 1-3rd sub-dam D1-c may be formed in the same process as the spacer IL7 positioned in the display area DA.

The second dam D2 may include a 2-1st sub-dam D2-a, a 2-2nd sub-dam D2-b, a 2-3rd sub-dam D2-c, and a 2-4th sub-dam D2-d. The 2-1st sub-dam D2-a may be positioned on the same layer as the first organic insulating layer IL4 positioned in the display area DA and may include the same material. The 2-1st sub-dam D2-a may be formed in the same process as the first organic insulating layer IL4 positioned in the display area DA. The 2-2nd sub-dam D2-b may be positioned on the same layer as the second organic insulating layer IL5 positioned in the display area DA and may include the same material. The 2-2 sub-dam D2-b may be formed in the same process as the second organic insulating layer IL5 positioned in the display area DA. The 2-3 sub-dam D2-c may be positioned on the same layer as the pixel defining layer IL6 positioned in the display area DA and may include the same material. The 2-3 sub-dam D2-c may be formed in the same process as the pixel defining layer IL6 positioned in the display area DA. The 2-4th sub-dam D2-d may be positioned on the same layer as the spacer IL7 positioned in the display area DA and may include the same material. The 2-4th sub-dam D2-d may be formed in the same process as the spacer IL7 positioned in the display area DA.

Meanwhile, in FIG. 4, the first dam D1 has a three-layer structure and the second dam D2 has a four-layer structure, but the present inventive concept is not necessarily limited thereto, and the number of layers of the first dam D1 and the second dam D2 may be variously changed. In addition, although it is illustrated that two dams are disposed in the peripheral area LA in FIG. 4, the present inventive concept is not necessarily limited thereto, and three or more dams may be disposed in the peripheral area LA.

The 1-1st layer FL-1 may be disposed on the first dam D1. The 1-2nd layer FL-2 may be disposed on the second dam D2. The 1-3rd layer FL-3 may be disposed between the second dam D2 and the opening area DTA. The 1-1st layer FL-1, the 1-2nd layer FL-2, and the 1-3rd layer FL-3 may include the same material as the functional layer FL and may be formed in the same process.

On each of the 1-1st layer FL-1, the 1-2nd layer FL-2, and the 1-3rd layer FL-3, a 2-1st layer E2-1, a 2-2nd layer E2-2, and a 2-3rd layer E2-3 may be disposed. The 2-1st layer E2-1, the 2-2nd layer E2-2, and the 2-3rd layer E2-3 may include the same material as the second electrode E2 and may be formed in the same process.

The first inorganic encapsulation layer EIL1 extending from the display area DA may be disposed in the peripheral area LA. Also, the end of the organic encapsulation layer EOL extending from the display area DA may be positioned in the peripheral area LA. The first dam D1 may control the spreading of the organic material in the process of forming the organic encapsulation layer EOL. The organic encapsulation layer EOL may fill a space between an end of the display area DA and the first dam D1. The second encapsulation inorganic layer EIL2 overlapping an entire surface of the substrate SUB may be positioned on the organic encapsulation layer EOL.

The first inorganic encapsulation layer EIL1, the organic encapsulation layer EOL, and the second encapsulation inorganic layer EIL2 may be sequentially disposed on the third inorganic insulating layer IL3 in the first disconnection area R1. In addition, the first encapsulation inorganic layer EIL1 and the second encapsulation inorganic layer EIL2 may be sequentially stacked on the third inorganic insulating layer IL3 in the second disconnection area R2 and the third disconnection area R3.

Meanwhile, the display device DD may further include an electronic module overlapping the opening area DTA. For example, the electronic module may be inserted into the opening area DTA. The electronic module may include various functional modules for operating the display device DD. For example, the electronic module may be a camera, a speaker, or a sensor for detecting light or heat.

An inner surface of the opening area DTA may be defined by an end of each of the substrate SUB, the buffer layer BF, the first inorganic insulating layer IL1, the second inorganic insulating layer IL2, the third inorganic insulating layer IL3, the 1-3rd layers FL-3, the 2-3rd layer E2-3, the first inorganic encapsulation layer EIL1, the second inorganic encapsulation layer EIL2, the overcoat layer YOC, the touch insulating layer YILD, and the planarization layer YPVX. However, the present inventive concept is not necessarily limited thereto, and some of the aforementioned components may be omitted or added to define the inner surface of the opening area DTA.

Meanwhile, the cross-sectional structures of the display area DA, the peripheral area LA, and the opening area DTA described with reference to FIGS. 3 and 4 are only examples and may be variously changed according to embodiments.

FIG. 5 is an enlarged view illustrating an enlarged area B of FIG. 1.

In FIG. 5, for convenience of description, the data lines DL, a data pad lines DPL, a data bending lines DBL, the transfer line part TLP, a first power line VSL, a first power pad lines VSPL, a first power bending lines VSBL, a second power line VDL, a second power pad lines VDPL, and a second power bending lines VDBL are illustrated.

Referring to FIGS. 1 and 5, the data pad lines DPL may be disposed in the second area A2. The data pad lines DPL may be disposed between the data driver DDV and the data bending lines DBL. One end of each of the data pad lines DPL may be connected to corresponding data bending line DBL through a first data contact hole DCT1 and the other end of the each of the data pad lines DPL may be connected to the data driver DDV.

The data bending lines DBL may be disposed in the first area A1, the second area A2, and the bending area BA. The data bending lines DBL may be disposed between the transfer line part TLP and the data pad lines DPL. One end of each of the data bending lines DBL may be connected to the transfer line part TLP through a second data contact hole DCT2, and the other end of the each of the data bending lines DBL may be connected to corresponding data pad line DPL through the first data contact hole DCT1.

The transfer line part TLP may be disposed in the non-display area NDA and the first area A1. The transfer line part TLP may include transfer lines. The transfer line part TLP may be disposed between the data lines DL and the data bending lines DBL. One end of each of the transfer lines may be connected to corresponding data line DL through a third data contact hole DCT3, and the other end of the each of the transfer lines may be connected to corresponding data bending line DBL through the second data contact hole DCT2. In an embodiment, the transfer line part TLP may extend in the second direction DR2. That is, the transfer line part TLP may extend in a direction that obliquely intersects the first direction DR1.

Meanwhile, in FIG. 5, scan control lines connected to the scan driver SDV are omitted for convenience of description, but each of the scan control lines (not shown) may include a scan transfer line, a scan pad line, and a scan bending line, and the scan transfer line part may be substantially the same as the transfer line part TLP, the scan pad line may be substantially the same as the data pad line DPL, and the scan bending line may be substantially the same as the data bending line DBL.

The first power line VSL may be disposed in the non-display area NDA. The first power line VSL may overlap the second non-display area NDA2. The first power line VSL may overlap the transfer line part TLP in a plan view.

The first power bending lines VSBL may be disposed in the first area A1, the second area A2, and the bending area BA. The first power bending lines VSBL may be disposed between the first power lines VSL and the first power pad lines VSPL. The first power bending lines VSBL may extend from the first power lines VSL. The first power bending lines VSBL may be integrally formed with the first power lines VSL. That is, the first power bending lines VSBL may be formed of the same material as the first power lines VSL. Each of the first power bending lines VSBL may be connected to corresponding first power pad line VSPL through a first line contact hole VSH.

The first power pad lines VSPL may be disposed in the second area A2. The first power pad lines VSPL may be disposed between the first power bending lines VSBL and the pad part PD. One end of each of the first power pad lines VSPL may be connected to corresponding first power bending line VSBL through the first line contact hole VSH, and the other end of each of the first power pad line VSPL may be connected to the pad part PD.

The second power line VDL may be disposed in the non-display area NDA. The second power line VDL may overlap the second non-display area NDA2. The second power line VDL may overlap the transfer line part TLP.

The second power bending lines VDBL may be disposed in the first area A1, the second area A2, and the bending area BA. The second power bending lines VDBL may be disposed between the second power line VDL and the second power pad lines VDPL. The second power bending lines VDBL may extend from the second power lines VDL. The second power bending lines VDBL may be integrally formed with the second power line VDL. That is, the second power bending lines VDBL may be formed of the same material as the second power line VDL. Each of the second power bending lines VDBL may be connected to corresponding second power pad line VDPL through the second line contact hole VDH.

The second power pad lines VDPL may be disposed in the second area A2. The second power pad lines VDPL may be disposed between the second power bending lines VDBL and the pad part PD. One end of each of the second power pad lines VDPL may be connected to corresponding second power bending line VDBL through a second line contact hole VDH, and the other end of each of the second power pad lines VDPL may be connected to the pad part PD.

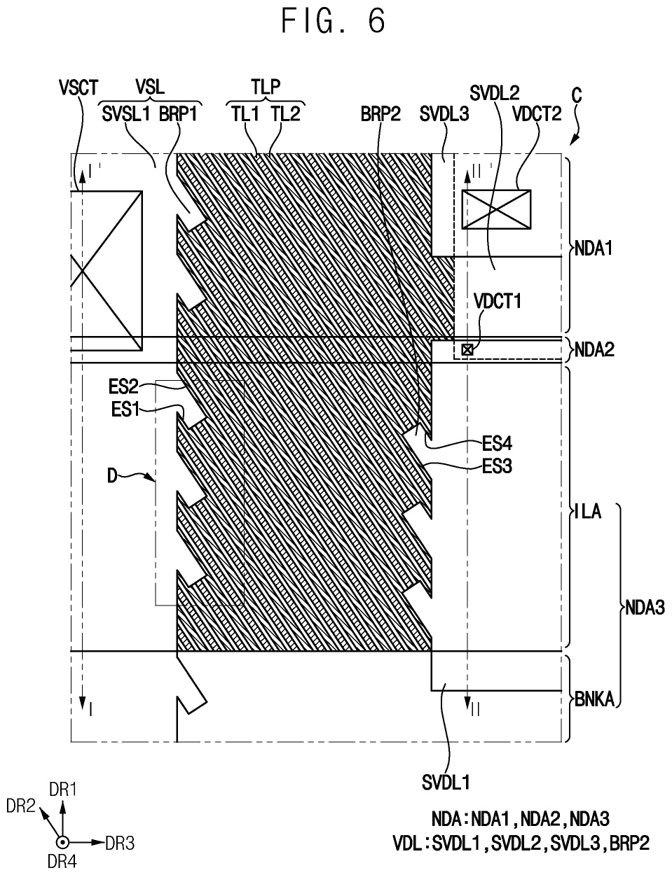

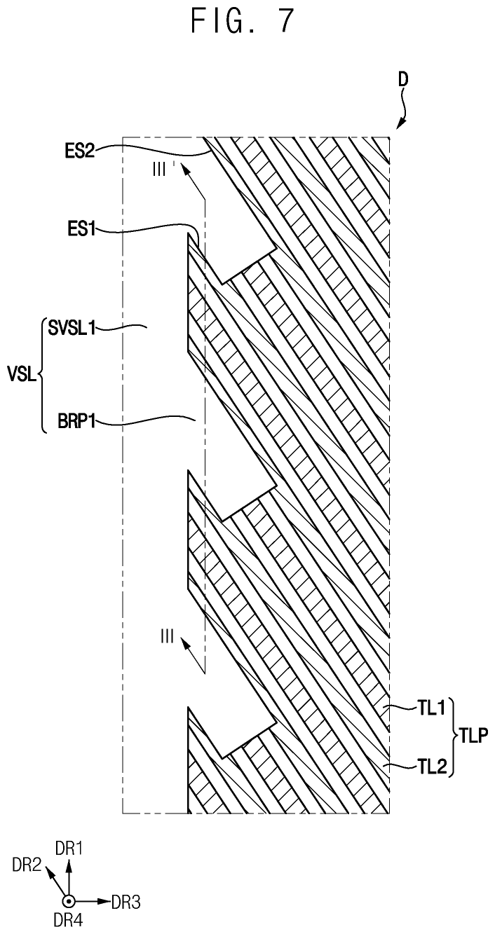

FIG. 6 is an enlarged view illustrating an example of area C of FIG. 5, and FIG. 7 is an enlarged view illustrating area D of FIG. 6.

Referring to FIGS. 5 to 7, the third non-display area NDA3 may include a bank area BNKA and an inorganic layer area ILA.

The bank area BNKA may be spaced apart from the first non-display area NDA1 with the second non-display area NDA2 and the inorganic layer area ILA interposed therebetween. The bank area BNKA may be an area where a bank (BNK in FIG. 8) for supporting a mask is disposed when the display device DD is manufactured. The bank area BNKA may be disposed in a direction opposite to the first direction DR1 in the non-display area NDA. A description of the bank BNK will be described later in detail with reference to FIG. 8.

The inorganic layer area ILA may be disposed between the second non-display area NDA2 and the bank area BNKA. One side of the inorganic layer area ILA may contact the second non-display area NDA2 and the other side of the inorganic layer area ILA may contact the bank area BNKA. The inorganic layer area ILA may be an area in which at least one organic layers are removed and only the inorganic layers are disposed. For example, The inorganic layer area ILA may be an area in which the first inorganic encapsulation layer (EIL1 in FIG. 3) and the second inorganic encapsulation layer (EIL2 in FIG. 3) of the encapsulation layer (ENC in FIG. 3) is in direct contact.

Meanwhile, as described above, the second non-display area NDA2 may be an area where the protruding member (PM in FIG. 8) is disposed.

The transfer line part TLP for transferring the data voltage to the data line DL may be disposed in the non-display area NDA. In detail, the transfer line part TLP may overlap the inorganic layer area ILA. The transfer line part TLP may include first transfer lines TL1 and second transfer lines TL2. Each of the first transfer lines TL1 and the second transfer lines TL2 may be connected to the data line DL.

The first transfer lines TL1 may extend in the second direction DR2. The second transfer lines TL2 may be disposed parallel to the first transfer lines TL1. That is, the second transfer lines TL2 may extend in the second direction DR2. In other words, the first transfer lines TL1 and the second transfer lines TL2 may extend in a direction obliquely intersecting the first direction DR1. The first transfer lines TL1 and the second transfer lines TL2 may be alternately arranged along a direction which perpendicularly intersects the second direction DR2.

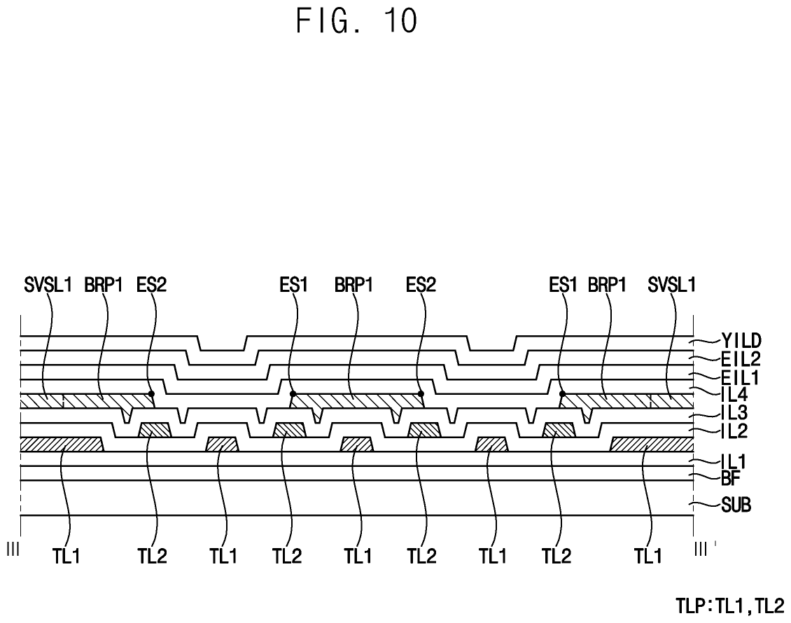

The first transfer lines TL1 may be disposed on the same layer as each other. The second transfer lines TL2 may be disposed on the same layer as each other. A layer on which the first transfer lines TL1 are disposed may be different from a layer on which the second transfer lines TL2 are disposed. For example, the layer on which the second transfer lines TL2 are disposed may be located above the layer on which the first transfer lines TL1 are disposed. This will be described later in more detail with reference to FIG. 10.

The first power line VSL for supplying a first power voltage to the second electrode (E2 in FIG. 3) may be disposed in the non-display area NDA. The first power line VSL may include a first sub power line SVSL1, a second sub power line (SVSL2 in FIG. 8), and a first branch BRP1. For example, the first power line VSL may include a plurality of first branches BRP1. Since the second sub power line SVSL2 is disposed below the first sub power line SVSL1, illustration of the second sub power line SVSL2 is omitted in FIG. 6.

The first sub power line SVSL1 may extend in the first direction DR1. For example, the first sub power line SVSL1 may be disposed in the first non-display area NDA1, the second non-display area NDA2, the inorganic layer area ILA, and the bank area BNKA. The first sub power line SVSL1 may be connected to the second sub power line SVSL2 through a first power contact hole VSCT. As a result, resistance of the first power line VSL may be lowered.

In the inorganic layer area ILA, due to an inclination of a side surface of the first sub power line SVSL1, the first sub power line SVSL1 may not be covered properly by the first and second inorganic encapsulation layers EIL1 and EIL2. That is, in the inorganic layer area ILA, a gap may occur in the first inorganic encapsulation layer EIL1 and the second inorganic encapsulation layer EIL2 due to the inclination of the side surface of the first sub power line SVSL1. The gap may be a permeable passage for external air or moisture.

The first branch BRP1 may protrude from one side of the first sub power line SVSL1. The first branch BRP1 may be disposed in the inorganic layer area ILA. Also, the first branch BRP1 may be disposed in the first non-display area NDA1, the second non-display area NDA2, and the bank area BNKA, but the present inventive concept is not necessarily limited thereto. The first branch BRP1 may be omitted in at least one of the first non-display area NDA1, the second non-display area NDA2, and the bank area BNKA.

In the inorganic layer area ILA, a portion having a bad step coverage may be formed along the side surface of the first sub power line SVSL1. Accordingly, a permeation path of external air or moisture through the portion having the bad step coverage in the inorganic layer area ILA may be formed along the side surface of the first sub power line SVSL1. Since the first power line VSL1 includes the first branch BRP1, a length of the side surface of the first power line VSL may include a length of the circumference of the first branch BRP1. Accordingly, a length of the side surface of the first power line VSL when the first branch BRP1 is included may be longer than a length of the side surface of the first power line VSL when the first branch BRP1 is not included. Accordingly, the moisture permeation path may be relatively long. Therefore, even if the portion having the bad step coverage is formed along the side surface of the first sub power line SVSL1 in the inorganic layer area ILA, permeation of external air or moisture to the display area DA may be delayed or prevented.

Meanwhile, the first branch BRP1 may have a first edge ES1 and a second edge ES2 entirely overlapped with the transfer line part TLP in a plan view. In other words, the first edge ES1 and the second edge ES2 of the first branch BRP1 may not be overlapped with a space between the first transfer lines TL1 and the second transfer lines TL2 in a plan view. In this case, the first edge ES1 and the second edge ES2 may be edges that have one end in contact with the first sub power line SVSL1.

In an embodiment, the first edge ES1 may be entirely overlapped with one of the second transfer lines TL2 in a plan view, and the second edge ES2 may be entirely overlapped with another one of the second transfer lines TL2 in a plan view. Accordingly, the first branch BRP1 may overlap a portion of at least one of the first transfer lines TL1 in a plan view. For example, as shown in FIGS. 6 and 7, one of the first transfer lines TL1 may be disposed between the second transfer line TL2 on which the first edge ES1 is disposed in a plan view and the second transfer line TL2 on which the second edge ES2 is disposed in a plan view. Accordingly, the first branch BRP1 may overlap a portion of one of the first transfer lines TL1 in a plan view.

However, the present inventive concept is not necessarily limited thereto, and the number of the first transfer lines TL1 disposed between the second transfer line TL2 in which the first edge ES1 overlaps in a plan view and the second transfer line TL2 in which the second edge ES2 overlaps in a plan view may be variously changed according to an area (or a size) of the first branch BRP1. For example, two of the first transfer lines TL1 may be disposed between the second transfer line TL2 in which the first edge ES1 overlaps in a plan view and the second transfer line TL2 in which the second edge ES2 overlaps in a plan view. Accordingly, the first branch BRP1 may overlap a portion of each of the two of the first transfer lines TL1 in a plan view.

In addition, in FIG. 6, the area of the first branch BRP1 included in the first power line VSL is all shown to be the same, but the present inventive concept is not necessarily limited thereto. That is, the number of first transfer lines TL1 overlapped with the first branch BRP1 may not be the same for each of the first branches BRP1. For example, at least one of the first branches BRP1 may overlap a portion of one of the first transfer lines TL1 in a plan view, and another one of the first branches BRP1 may overlap a portion of each of the two of the first transfer lines TL1 in a plan view.

As a transfer line overlapping the first edge ES1 in a plan view and a transfer line overlapping the second edge ES2 in a plan view are disposed on the same layer, a step difference due to the first branch BRP1 may be reduced or prevented.

The first branch BRP1 may protrude from one side of the first sub power line SVSL1 such that the first edge ES1 and the second edge ES2 are parallel to the first transfer lines TL1 and the second transfer lines TL2. For example, the first edge ES1 and the second edge ES2 may extend from one side of the first sub power line SVSL1 in a direction opposite to the second direction DR2. In an embodiment, the first edge ES1 and the second edge ES2 may have a straight-line shape extending parallel to the first transfer lines TL1 and the second transfer lines TL2.

When the first edge ES1 and the second edge ES2 of the first branch BRP1 overlap the space between the first transfer lines TL1 and the second transfer lines TL2, the first power line VSL (e.g., the first branch BRP1) may be easily damaged by external pressure or the like. On the other hand, according to the embodiments, the first edge ES1 and the second edge ES2 of the first branch BRP1 may be entirely overlapped with the transfer line part TLP in a plan view. In addition, the first edge ES1 and the second edge ES2 of the first branch BRP1 may extend parallel to the transfer line part TLP. Accordingly, damage to the first power line VSL due to external pressure or the like may be reduced or prevented. Accordingly, durability of the display device DD may be improved.

In particular, when the display device DD includes the first disconnection area R1, the second disconnection area R2, and the third disconnection area R3 of FIG. 4, the process of forming the sacrificial layer may be accompanied. Accordingly, in the process of forming the sacrificial layer, additional damage to the first power line VSL may be caused. Accordingly, the portion having the bad step coverage through which external air or moisture permeates may more easily occur in the inorganic layer area ILA. According to the embodiments, the first power line VLS1 may have the first branch BRP1 protruding from one side of the first sub power line SVSL1. In addition, the first edge ES1 and the second edge ES2 of the first branch BRP1 may be entirely overlapped with the transfer line part TLP in a plan view. In addition, the first edge ES1 and the second edge ES2 of the first branch BRP1 may extend parallel to the transfer line part TLP. Accordingly, the moisture permeation path is increased, and damage to the first power line VSL due to external pressure or the like may be reduced or prevented. Therefore, even after the process of forming the sacrificial layer, permeation of external air or moisture through the gap in the inorganic layer area ILA may be reduced or prevented. Accordingly, durability of the display device DD may be improved.

The second power line VDL may be spaced apart from the first power line VSL. The second power line VDL may supply a second power voltage having a higher potential than the first power voltage to the display area DA. The second power line VDL may include a third sub power line SVDL1, a fourth sub power line SVDL2, a fifth sub power line SVDL3, and a second branch BRP2. For example, the second power line VDL may include a plurality of second branches BRP2.

The third sub power line SVDL1, the fourth sub power line SVDL2, and the fifth sub power line SVDL3 may extend in the first direction DR1. For example, the third sub power line SVDL1 may be disposed in the second non-display area NDA2, the inorganic layer area ILA, and the bank area BNKA. The fourth sub power line SVDL2 may be disposed in the first non-display area NAD1 and the second non-display area NDA2. The third sub power line SVDL3 may be connected to the fourth sub power line SVDL2 through a second power contact hole VDCT1. The fifth sub power line SVDL3 may be disposed in the first non-display area NDA1. The fifth sub power line SVDL3 may be connected to the fourth sub power line SVDL2 through a third power contact hole VDCT2.

In the inorganic layer region ILA, due to an inclination of a side surface of the third sub power line SVDL1, the third sub power line SVDL1 may not be covered properly by the first and second inorganic encapsulation layers EIL1 and EIL2. That is, in the inorganic layer area ILA, a portion having the bad step coverage may occur in the first inorganic encapsulation layer EIL1 and the second inorganic encapsulation layer EIL2 due to the inclination of the side surface of the third sub power line SVDL1. The portion having the bad step coverage may be a permeable passage for external air or moisture.

The second branch BRP2 may protrude from one side of the third sub power line SVDL1. The second branch BRP2 may be disposed on the inorganic layer area ILA. Also, the second branch BRP2 may not be disposed in the first non-display area NDA1, the second non-display area NDA2, and the bank area BNKA, but the present inventive concept is not necessarily limited thereto. The first branch BRP1 may be additionally disposed in at least one of the first non-display area NDA1, the second non-display area NDA2, and the bank area BNKA.

In the inorganic layer area ILA, the portion having the bad step coverage may be formed along the side surface of the third sub power line SVDL1. Accordingly, a moisture permeation path of external air or moisture through the portion having the bad step coverage in the inorganic layer area ILA may be formed along the side surface of the third sub power line SVDL1. Since third sub power line SVDL1 includes the second branch BRP2, a length of the side surface of the second power line VDL may include a length of the circumference of the second branch BRP2. Accordingly, a length of the side surface of second power line VDL when the second branch BRP2 is included may be longer than a length of the side surface of second power line VDL when the second branch BRP2 is not included. Accordingly, the moisture permeation path may be relatively long. Therefore, even if the portion having the bad step coverage is formed along the side surface of third sub power line SVDL1 in the inorganic layer area ILA, permeation of external air or moisture may be delayed or prevented.

Meanwhile, the second branch BRP2 may have a third edge ES3 and a fourth edge ES4 entirely overlapped with the transfer line part TLP in a plan view. In other words, the third edge ES3 and the fourth edge ES4 of the second branch BRP2 may not be overlapped with a space between the first transfer lines TL1 and the second transfer lines TL2 in a plan view. In this case, the third edge ES3 and the fourth edge ES4 may be edges that have one end in contact with the third sub power line SVDL1.

In addition, the third and fourth edges ES3 and ES4 of the second branch BRP2 may extend from one side of the third sub power line SVDL1 in the second direction DR2. That is, the second branch BRP2 may protrude from one side of the third sub power line SVDL1 such that the third edge ES3 and the fourth edge ES4 are parallel to the first transfer lines TL1 and the second transfer lines TL2.

Meanwhile, since an arrangement relationship between the second branch BRP2 and the transfer line part TLP is substantially the same as an arrangement relationship between the first branch BRP1 and the transfer line part TLP, a detailed description thereof will be omitted.

According to embodiments, the third edge ES3 and the fourth edge ES4 of the second branch BRP2 may be entirely overlapped with the transfer line part TLP in a plan view. In addition, the third and fourth edges ES3 and ES4 of the second branch BRP2 may extend parallel to the transfer line part TLP. Accordingly, damage to the second power line VDL due to external pressure or the like may be reduced or prevented. Accordingly, durability of the display device DD may be improved.

FIG. 8 is a cross-sectional view taken along line I-I′ of FIG. 6.

Referring to FIG. 8, the first power line VSL may include the first sub power line SVSL1 and the second sub power line SVSL2. The protruding member PM may include a first sub protruding member SPM1, a second sub protruding member SPM2, a third sub protruding member SPM3, and a fourth sub protruding member SPM4. The protruding member PM may be disposed in the second non-display area NDA2. Although FIG. 8 illustrates that one protruding member PM is disposed in the second non-display area NDA2, the present inventive concept is not necessarily limited thereto. Two or more protruding members PM may be disposed in the second non-display area NDA2. A valley structure VLS may be a structure for forming a valley VAL between the valley structure VLS and the first organic insulating layer IL4, and may be disposed in the first non-display area NDA1. The valley structure VLS may include a first sub valley structure SVLS1 and a second sub valley structure SVLS2. The bank BNK may include a first sub bank SBNK1, a second sub bank SBNK2, a third sub bank SBNK3, and a fourth sub bank SBNK4.

The second sub power line SVSL2 may be included in the first data conductive layer SD1 and may be disposed on the third inorganic insulating layer IL3. That is, the second sub power line SVSL2 may be formed of the same material and disposed on the same layer as the source electrode (SE of FIG. 3) and the drain electrode (DE of FIG. 3). The source electrode SE, the drain electrode DE, and the second sub power line SVSL2 may be different portions of one conductive pattern. The second sub power line SVSL2 may be disposed in the first non-display area NDA1 and the second non-display area NDA2. The second sub power line SVSL2 may overlap the protruding member PM and the valley structure VLS in the fourth direction DR4.

The first sub protruding member SPM1 may be disposed on the second sub power line SVSL2. The first sub bank SBNK1 may be disposed on the third inorganic insulating layer IL3. The first sub protruding member SPM1 and the first sub bank SBNK1 may be formed of the same material as the first organic insulating layer IL4 and may be disposed on the same layer.

The first sub power line SVSL1 may be included in the second data conductive layer SD2 and disposed on the first organic insulating layer IL4, the first sub protruding member SPM1, and the first sub bank SBNK1. That is, the second sub power line SVSL2 may be formed of the same material and disposed on the same layer as the connection electrode (CE of FIG. 3). The connection electrode CE and the second sub power line SVSL2 may be different portions of one conductive pattern. The first sub power line SVSL1 may be connected to the second sub power line SVSL2 through the first power contact hole VSCT. The first power contact hole VSCT may be disposed in the second non-display area NDA2 and the first non-display area NDA1.

A thicknesses of the second sub protrusion member SPM2 and the second sub bank SBNK2 may be thinner than a thickness of the first sub valley structure SVLS1 and the second organic insulating layer IL5. The first sub valley structure SVLS1 and the second organic insulating layer IL5 may be connected. A thickness of a connection portion connecting the first sub valley structure SVLS1 and the second organic insulating layer IL5 may be thinner than the thicknesses of the first sub valley structure SVLS1 and the second organic insulating layer IL5.

The third sub protruding member SPM3 may be disposed on the second sub protruding member SPM2, the second sub valley structure SVLS2 may be disposed on the first sub valley structure SVLS1, and the third sub bank SBNK3 may be disposed on the second sub bank SBNK2. The third sub protruding member SPM3, the second sub valley structure SVLS2, and the third sub bank SBNK3 may be formed of the same material and disposed on the same layer as the pixel defining layer IL6.

In an embodiment, the third sub protruding member SPM3 may cover the second sub protruding member SPM2. For example, the third sub protruding member SPM3 may be disposed on upper and side surfaces of the second sub protruding member SPM2. Also, the second sub valley structure SVLS2 may cover the first sub valley structure SVLS1. For example, the second sub valley structure SVLS2 may be disposed on upper and side surfaces of the first sub valley structure SVLS1. Also, the third sub bank SBNK3 may cover the second sub bank SBNK2. For example, the third sub bank SBNK3 may be disposed on upper and side surfaces of the second sub bank SBNK2.

The fourth sub protruding member SPM4 may be disposed on the third sub protruding member SPM3, and the fourth sub bank SBNK4 may be disposed on the third sub bank SBNK3. The third sub protruding member SPM3 and the fourth sub bank SBNK4 may be formed of the same material and disposed on the same layer.

The first inorganic encapsulation layer EIL1 may be disposed in the first non-display area NDA1, the second non-display area NDA2, the inorganic layer area ILA, and the bank area BNKA. The first inorganic encapsulation layer EIL1 may be disposed on the pixel defining layer IL6, the spacer IL7, the valley structure VLS, the protruding member PM, the first sub power line VSL1, and the bank BNK. The organic encapsulation layer EOL may be disposed in the first non-display area NDA1 and the second non-display area NDA2. The organic encapsulation layer EOL may not be disposed in an area outside of the protruding member PM. Accordingly, the first inorganic encapsulation layer EIL1 and the second inorganic encapsulation layer EIL2 may directly contact each other in the inorganic layer area ILA. As a result, an inorganic encapsulation structure may be formed in the inorganic layer area ILA. The second inorganic encapsulation layer EIL2 may be disposed in the first non-display area NDA1, the second non-display area NDA2, the inorganic layer area ILA, and the bank area BNKA. Also, in an embodiment, the touch insulating layer YILD may be disposed in the first non-display area NDA1, the second non-display area NDA2, the inorganic layer area ILA, and the bank area BNKA. For example, the touch insulating layer YILD and the second inorganic encapsulation layer EIL2 may directly contact each other in the inorganic layer area ILA.

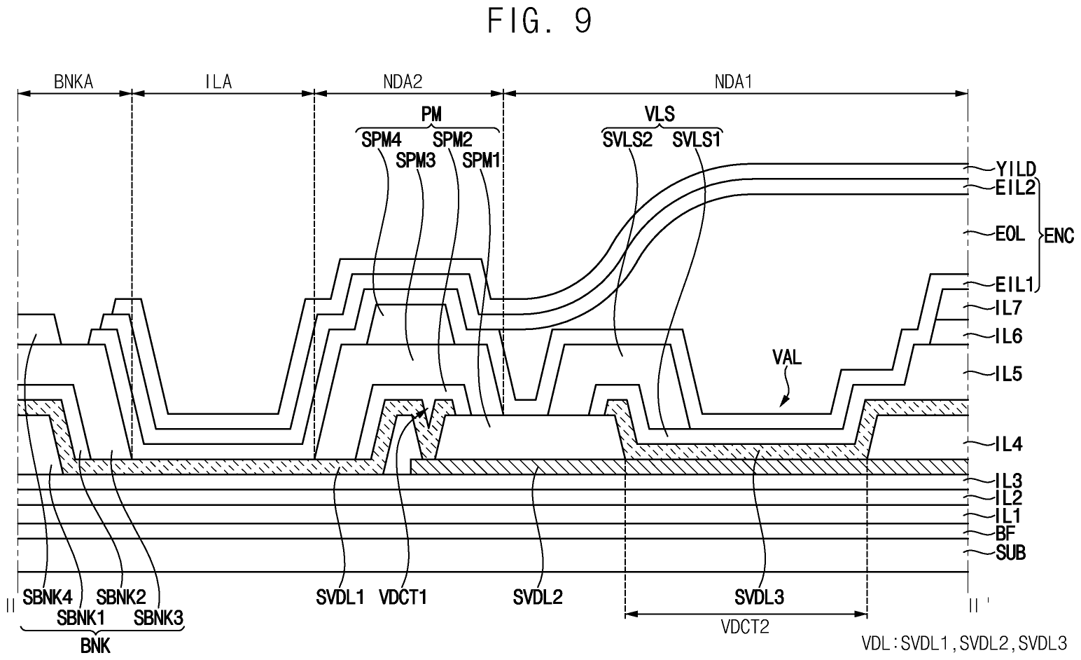

FIG. 9 is a cross-sectional view taken along line II-II′ of FIG. 6.

Referring to FIG. 9, the second power line VDL may include the third sub power line SVDL1, the fourth sub power line SVDL2, and the fifth sub power line SVDL3.

The fourth sub power line SVDL2 may be included in the first data conductive layer SD1 and may be disposed on the third inorganic insulating layer IL3. That is, the fourth sub power line SVDL2 may be formed of the same material and disposed on the same layer as the source electrode (SE of FIG. 3), the drain electrode (DE of FIG. 3), and the second sub power line SVSL2. The source electrode SE, the drain electrode DE, the first sub power line SVSL1 and the second sub power line SVSL2 may be different portions of one conductive pattern. The fourth sub power line SVDL2 may be disposed in the first non-display area NDA and the second non-display area NDA2. The fourth sub power line SVDL2 may overlap the protruding member PM and the valley structure VLS in the fourth direction DR4.

The third sub power line SVDL1 may be included in the second data conductive layer SD2 and may be disposed on the first sub protruding member SPM1 and the first sub bank SBNK1. The third sub power line SVDL1 may be connected to the fourth sub power line SVDL2 through the second power contact hole VDCT1. The second power contact hole VDCT1 may be disposed in the second non-display area NDA2.

The fifth sub power line SVDL3 may be included in the second data conductive layer SD2 and may be disposed on the first sub protruding member SPM1 and the first organic insulating layer IL4. The fifth sub power line SVDL3 may be connected to the fourth sub power line SVDL2 through the third power contact hole VDCT2. The third power contact hole VDCT2 may be disposed in the first non-display area NDA1.

The third sub power line SVDL1 and the fifth sub power line SVDL3 may be formed of the same material and may be disposed on the same layer as the connection electrode (CE of FIG. 3) and the first sub power line SVSL1. The connection electrode CE, the first sub power line SVLS1, the third sub power line SVDL1, and the fifth sub power line SVDL3 may be different portions of one conductive pattern.

The second sub protruding member SPM2 and the second sub bank SBNK2 may be disposed on the third sub power line SVDL1. The first sub valley structure SVLS1 and the second organic insulating layer IL5 may be disposed on the fifth sub power line SVDL3.

In addition, since the protruding member PM, the valley structure VLS, the bank BNK, the encapsulation layer ENC, and the touch insulating layer YILD may be substantially the same as those described with reference to FIG. 8. Therefore, redundant description is omitted.

FIG. 10 is a cross-sectional view taken along line I-III′ of FIG. 7.

Referring to FIG. 10, the first transfer lines TL1 may be a portion of the first gate conductive layer (GAT1 of FIG. 3) and disposed on the first inorganic insulating layer IL1. That is, the first transfer lines TL1 may be formed of the same material and disposed on the same layer as the gate electrode (GE of FIG. 3) and the first capacitor electrode (CSE1 of FIG. 3). In other words, the gate electrode GE, the first capacitor electrode CSE1, and the first transfer lines TL1 may be different portions of one conductive pattern.

The second transfer lines TL2 may be a portion of the second gate conductive layer (GAT2 of FIG. 3) and disposed on the second inorganic insulating layer IL2. That is, the layer on which the second transfer lines TL2 are disposed may be located above the layer on which the first transfer lines TL1 are disposed. For example, the second transfer lines TL2 may be formed of the same material and disposed on the same layer as the upper electrode (AE of FIG. 3) and the second capacitor electrode (CSE2 of FIG. 3). In other words, the upper electrode AE, the second capacitor electrode CSE2, and the second transfer lines TL2 may be different portions of one conductive pattern.

As described above, the first transfer lines TL1 and the second transfer lines TL2 may be alternately arranged. For example, the second transfer lines TL2 may be disposed between the first transfer lines TL1, respectively.

As the layer on which the first transfer lines TL1 are disposed is different from the layer on which the second transfer lines TL2 are disposed, a distance between the transfer lines forming the transfer line part TLP may be reduced. Accordingly, an area (or a size) in which the transfer line part TLP is disposed may be reduced. Accordingly, the non-display area of the display device DD may be reduced.

In the inorganic layer area ILA, the first sub power line SVSL1 and the first branch BRP1 may be disposed on the third inorganic insulating layer IL3. That is, a layer on which the first sub power line SVSL1 and the first branch BRP1 are disposed may be located above a layer on which the transfer line part TLP is disposed. The first sub power line SVSL1 and the first branch BRP1 may be integrally formed. That is, the first sub power line SVSL1 and the first branch BRP1 may be disposed on the same layer and formed of the same material.

As described above, the first edge ES1 and the second edge ES2 of the first branch BRP1 may be entirely overlapped with the transfer line part TLP in a plan view. In other words, the first edge ES1 and the second edge ES2 of the first branch BRP1 may not be overlapped with the space between the first transfer lines TL1 and the second transfer lines TL1 in a plan view. For example, the first edge ES1 may be entirely overlapped with one of the second transfer lines TL2 in a plan view, and the second edge ES2 may be entirely overlapped with another one of the second transfer lines TL2 in a plan view. Accordingly, damage to the first power line VSL due to external pressure or the like may be reduced or prevented. Accordingly, durability of the display device DD may be improved.

Meanwhile, although not shown, an arrangement relationship between the second branch BRP2 and the transfer line part TLP in a cross-section view may be substantially the same as an arrangement relationship between the first branch BRP1 and the transfer line part TLP shown in FIG. 10. Therefore, a detailed description is omitted.

According to embodiments, the display device may include the transfer line part and the power line disposed on the transfer line part, and the power line may include the sub power line and the branch protruding from one side of the sub power line. Accordingly, a length of a side surface of the power line may be longer than a length of a side surface of the power line not including the branch. Accordingly, a moisture permeation path of external air or moisture may be relatively long. Accordingly, permeation of external air or moisture through the side surface of the power line may be delayed or prevented.

In addition, the branch may protrude from one side of the sub power line such that edges are entirely overlapped with the transfer line part in a plan view. Also, the edges of the branch may extend parallel to the transfer line part. Accordingly, damage to the power line (e.g., the branch) due to external pressure or the like may be reduced or prevented. Accordingly, durability of the display device may be improved.

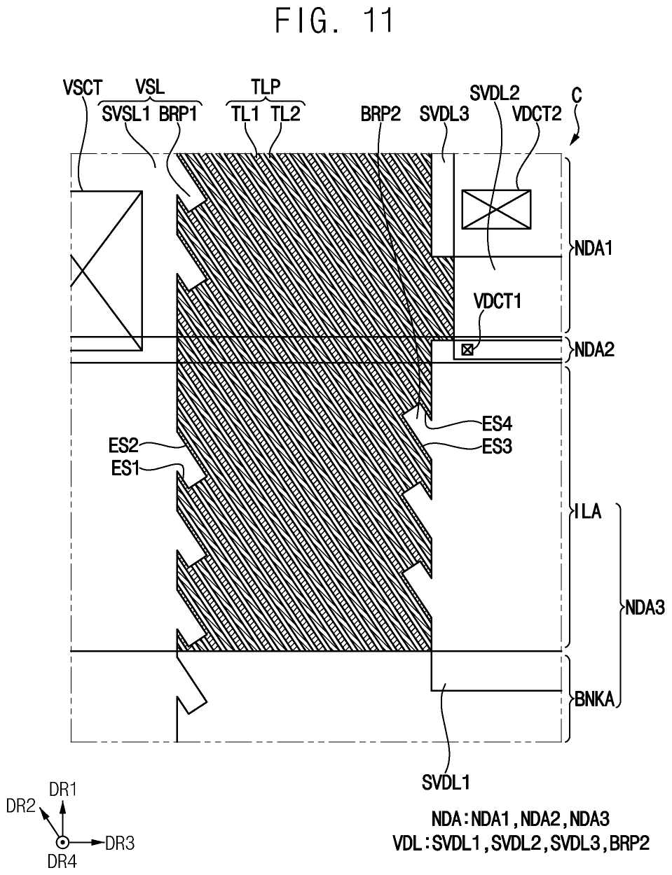

FIG. 11 is an enlarged view illustrating an example of area C of FIG. 5. For example, FIG. 11 may correspond to an enlarged view of FIG. 6.

Referring to FIG. 11, in an embodiment, the first edge ES1 of the first branch BRP1 may be entirely overlapped with one of the first transfer lines TL1 in a plan view, and the second edge ES2 may be entirely overlapped with another one of the first transfer lines TL1 in a plan view. Accordingly, the first branch BRP1 may overlap a portion of at least one of the second transfer lines TL2 in a plan view. For example, as shown in FIG. 11, one of the second transfer lines TL2 may be disposed between the first transfer line TL1 on which the first edge ES1 is disposed in a plan view and the first transfer line TL1 on which the second edge ES2 is disposed in a plan view. Accordingly, the first branch BRP1 may overlap a portion of one of the second transfer lines TL2 in a plan view.

However, the present inventive concept is not necessarily limited thereto, and according to an area (or a size) of the first branch BRP1, the number of second transfer lines TL2 disposed between the first transfer line TL1 where the first edge ES1 is disposed in a plan view and the first transfer line TL1 where the second edge ES2 is disposed in a plan view may be variously changed. For example, two of the second transfer lines TL2 may be disposed between the first transfer line TL1 where the first edge ES1 is disposed in a plan view and the first transfer line TL1 where the second edge ES2 is disposed in a plan view. Accordingly, the first branch BRP1 may overlap a portion of each of the two second transfer wires TL2 in a plan view.

Meanwhile, the third and fourth edges ES3 and ES4 of the second branch BRP2 may also be entirely overlapped with the first transfer lines TL1 in a plan view. For example, the third edge ES3 may be entirely overlapped with one of the first transfer lines TL1 in a plan view, and the fourth edge ES4 may be overlapped with another one of the first transfer lines TL1 in a plan view.

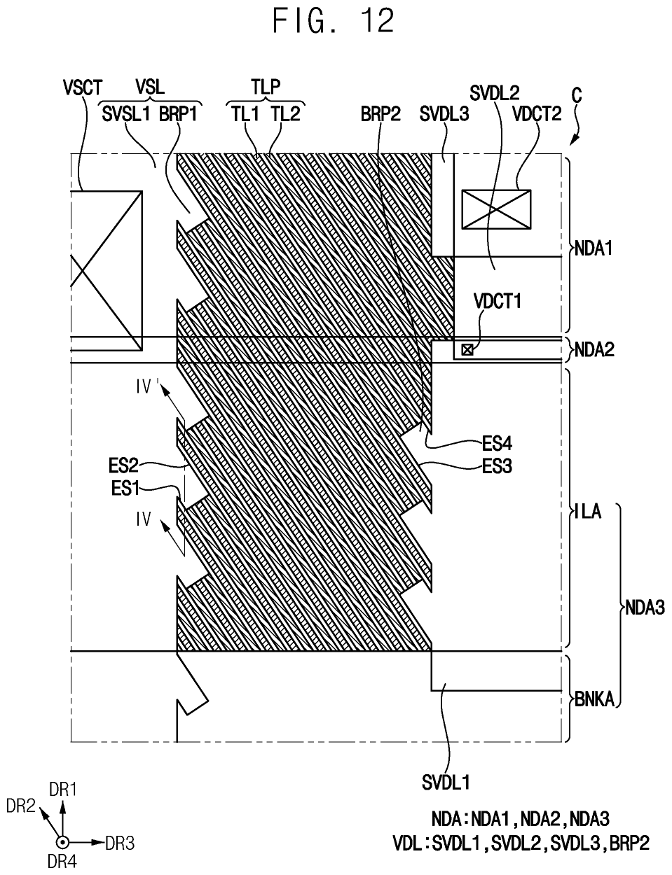

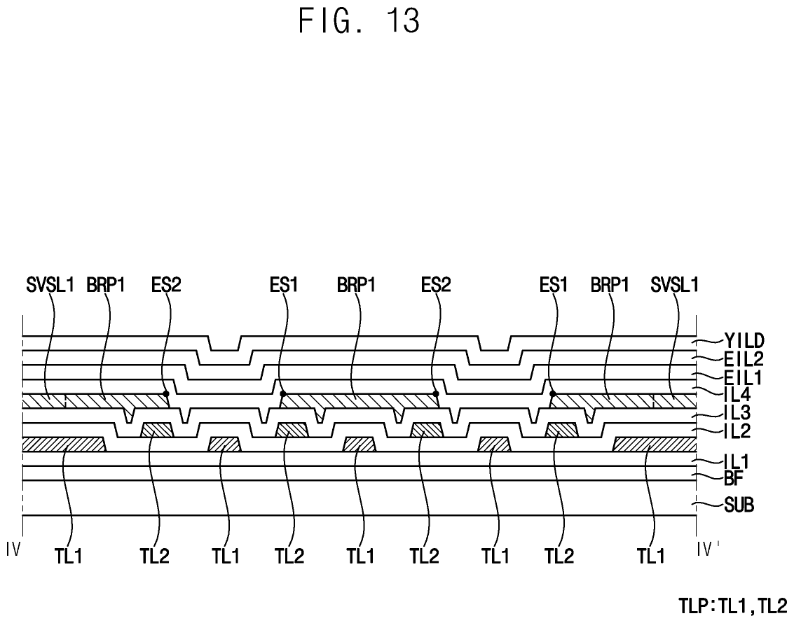

FIG. 12 is an enlarged view illustrating an example of area C of FIG. 5, and FIG. 13 is a cross-sectional view taken along line IV-IV of FIG. 12. For example, FIG. 12 may correspond to an enlarged view of FIG. 6 and FIG. 13 may correspond to a cross-sectional view of FIG. 10.

Referring to FIGS. 12 and 13, in an embodiment, the first edge ES1 and the second edge ES2 may be aligned with an edge of the second transfer lines TL2 in a plan view. For example, the first edge ES1 may be aligned with one edge of corresponding second transfer line TL2 in a plan view, and the second edge ES2 may be aligned with one edge of corresponding second transfer line TL2 in a plan view.

Meanwhile, although not shown, in another example, the first edge ES1 and the second edge ES2 may be aligned with an edge of the first transfer lines TL1 in a plan view. For example, the first edge ES1 may be aligned with one edge of corresponding first transfer lines TL1 in a plan view, and the second edge ES2 may be aligned with one edge of corresponding first transfer lines TL1 in a plan view.

In addition, although not shown, an arrangement relationship between the second branch BRP2 and the transfer line part TLP in a cross-section view may be substantially the same as an arrangement relationship between the first branch BRP1 and the transfer line part TLP shown in FIG. 13. Therefore, a detailed description is omitted.

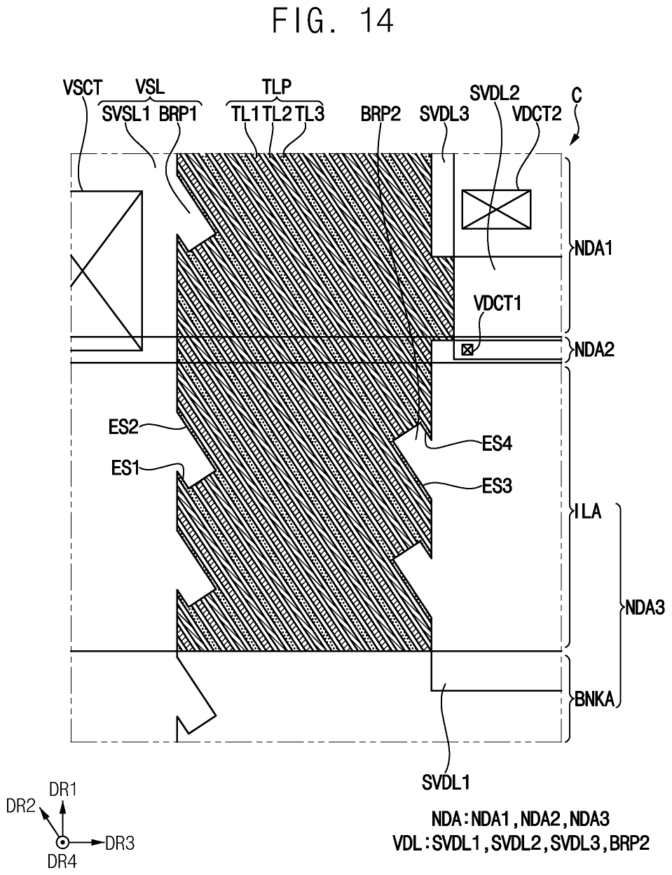

FIG. 14 is an enlarged view illustrating an example of area C of FIG. 5. For example, FIG. 14 may correspond to an enlarged view of FIG. 6.

Referring to FIG. 14, the transfer line part TLP may further include third transfer lines TL3. The third transfer lines TL3 may be disposed on the same layer as each other. A layer on which the third transfer lines TL3 are disposed may be different from a layer on which the first transfer lines TL1 are disposed and a layer on which the second transfer lines TL2 are disposed. For example, the third transfer lines TL3 may be disposed on the first inorganic insulating layer (IL1 in FIG. 10), and an additional sub insulating layer may be disposed on the first inorganic insulating layer IL1 and the third transfer lines TL3, and the first transfer lines TL1 may be disposed on the sub insulating layer.

However, the present inventive concept is not necessarily limited thereto, and in another example, the layer on which the third transfer lines TL3 are disposed may be located above the layer on which the first transfer lines TL1 are disposed and the layer on which the second transfer lines TL2 are disposed. In another example, the layer on which the third transfer lines TL3 are disposed may be positioned between the layer on which the first transfer lines TL1 are disposed and the layer on which the second transfer lines TL2 are disposed.

The third transfer lines TL3 may be disposed parallel to the first transfer lines TL1 and the second transfer lines TL2. That is, the third transfer lines TL3 may extend in the second direction DR2. In other words, the third transfer lines TL3 may extend in a direction that obliquely intersects the first direction DR1. The first transfer lines TL1, the second transfer lines TL2, and the third transfer lines TL3 may be alternately arranged.

In an embodiment, the first edge ES1 may be entirely overlapped with one of the third transfer lines TL3 in a plan view, and the second edge ES2 may be entirely overlapped with another one of the third transfer lines TL3 in a plan view. Accordingly, the first branch BRP1 may overlap a portion of at least one of the first transfer lines TL1 and a portion of at least one of the second transfer lines TL2 in a plan view. For example, as shown in FIG. 14, one of the first transfer lines TL1 and one of the second transfer lines TL2 may be disposed between the third transfer line TL3 on which the first edge ES1 is disposed in a plan view and the third transfer line TL3 on which the second edge ES2 is disposed in a plan view. Accordingly, the first branch BRP1 may overlap a portion of one of the first transfer lines TL1 and a portion of one of the second transfer lines TL2 in a plan view.

However, the present inventive concept is not necessarily limited thereto, and the number of the first transfer lines TL1 and the number of the second transfer lines TL2 disposed between the third transfer line TL3 on which the first edge ES1 is disposed in a plan view and the third transfer line TL3 on which the second edge ES2 is disposed in a plan view may be variously changed according to an area (or a size) of the first branch BRP1.

Meanwhile, the third and fourth edges ES3 and ES4 of the second branch BRP2 may also be entirely overlapped with the third transfer lines TL3 in a plan view. For example, the third edge ES3 may be entirely overlapped with one of the third transfer lines TL3 in a plan view, and the fourth edge ES4 may be entirely overlapped with another one of the third transfer lines TL3 in a plan view.

The inventive concept should not be construed as being limited to the embodiments set forth herein. Rather, these embodiments are provided so that this disclosure will be thorough and complete and will fully convey the concept of the inventive concept to those skilled in the art.

While the inventive concept has been particularly shown and described with reference to embodiments thereof, it will be understood by those of ordinary skill in the art that various changes in form and details may be made therein without departing from the spirit or scope of the inventive concept as defined by the following claims.

What is claimed is:

1. A display device comprising:
a substrate including a display area, a first non-display area surrounding the display area, a second non-display area surrounding the first non-display area, and a third non-display area including a bank area spaced apart from the first non-display area with the second non-display area interposed therebetween and an inorganic layer area disposed between the second non-display area and the bank area;
a data line disposed in the display area on the substrate and extending in a first direction;
a protruding member disposed in the second non-display area on the substrate and including an organic material;
a bank disposed in the bank area on the substrate and spaced apart from the protruding member;
a transfer line part disposed on the substrate, overlapping the inorganic layer area, and including first transfer lines extending in a second direction intersecting the first direction and second transfer lines disposed parallel to the first transfer lines and extending in the second direction; and
a power line disposed in the first to third non-display areas on the substrate and including a sub power line extending in the first direction and a branch protruding from one side of the sub power line and having a first edge and a second edge entirely overlapped with the transfer line part in a plan view.

2. The display device of claim 1, wherein the branch protrudes from the one side of the sub power line such that the first edge and the second edge extend parallel to the first transfer lines and the second transfer lines.

3. The display device of claim 1, wherein the first edge and the second edge have a straight-line shape extending parallel to the first transfer lines and the second transfer lines.

4. The display device of claim 1, wherein the first edge entirely overlaps with one of the first transfer lines in a plan view and the second edge entirely overlaps with another one of the first transfer lines in a plan view.

5. The display device of claim 1, wherein the first edge entirely overlaps with one of the second transfer lines in a plan view and the second edge entirely overlaps with another one of the second transfer lines in a plan view.

6. The display device of claim 1, wherein the second direction is a direction which obliquely intersects the first direction.

7. The display device of claim 1, wherein the first transfer lines and the second transfer lines are alternately arranged.

8. The display device of claim 1, wherein a layer on which the first transfer lines are disposed is different from a layer on which the second transfer lines are disposed.

9. The display device of claim 1, wherein the transfer line part further includes third transfer lines extending parallel to the first transfer lines and the second transfer lines,
wherein the first edge entirely overlaps with one of the third transfer lines in a plan view, and
wherein the second edge entirely overlaps with another one of the third transfer lines in a plan view.

10. The display device of claim 9, wherein the first transfer lines, the second transfer lines, and the third transfer lines are alternately arranged.

11. The display device of claim 9, wherein a layer on which the first transfer lines are disposed, a layer on which the second transfer lines are disposed, and a layer on which the third transfer lines are disposed are different from each other.

12. The display device of claim 1, further comprising:
a pixel electrode disposed in the display area;
a light emitting layer disposed on the pixel electrode;
a common electrode disposed on the light emitting layer;
a first inorganic encapsulation layer disposed on the common electrode;
an organic encapsulation layer disposed on the first inorganic encapsulation layer; and
a second inorganic encapsulation layer disposed on the organic encapsulation layer, and
wherein the first inorganic encapsulation layer and the second inorganic encapsulation layer directly contact each other in the inorganic layer area.

13. The display device of claim 12, wherein the substrate further includes a peripheral area surrounded by the display area and an opening area surrounded by the peripheral area, and
wherein the peripheral area includes a disconnection area in which the common electrode is disconnected.

14. The display device of claim 13, further comprising:
an electronic module overlapping the opening area in a plan view.

15. The display device of claim 13, wherein a dam including an organic material is disposed in the peripheral area, and
the disconnection area is located on both sides of the dam.

16. A display device comprising:
a substrate including a display area and a non-display area surrounding the display area;
a data line disposed in the display area on the substrate and extending in a first direction;
a transfer line part disposed in the non-display area on the substrate, connected to the data line, and including first transfer lines extending in a second direction intersecting the first direction and second transfer lines disposed parallel to the first transfer lines and extending in the second direction; and
a power line disposed in the non-display areas on the substrate and including a sub power line extending in the first direction and a branch protruding from one side of the sub power line and having a first edge and a second edge entirely overlapped with the transfer line part in a plan view.

17. The display device of claim 16, wherein the branch protrudes from the one side of the sub power line such that the first edge and the second edge extend parallel to the first transfer lines and the second transfer lines.

18. The display device of claim 16, wherein the first edge and the second edge have a straight-line shape extending parallel to the first transfer lines and the second transfer lines.

19. The display device of claim 16, wherein the second direction is a direction which obliquely intersects the first direction.

20. The display device of claim 16, wherein the first transfer lines and the second transfer lines are alternately arranged.
